(19) United States
(12) Patent Application Publication
(10) Pub. No.: US 2010/0052133 A1
(43) Pub. Date: Mar. 4, 2010

(54) STACK TYPE SEMICONDUCTOR DEVICE WITH REINFORCING RESIN

(75) Inventors: Hisashi TANIE, Hitachinaka-shi (JP); Hiroshi Moriya, Hitachinaka-shi (JP); Masahiro Yamaguchi, Tokyo (JP); Emi Sawayama, Tokyo (JP)

Correspondence Address: YOUNG & THOMPSON, 209 Madison Street, Suite 500, Alexandria, VA, 22314, US

(73) Assignee: Elpida Memory, Inc., Tokyo (JP)

(21) Appl. No.: 12/496,066

(22) Filed: Jul. 1, 2009

(30) Foreign Application Priority Data
Aug. 26, 2008 (JP) 2008-216033

(51) Int. Cl. H01L 23/52; H01L 21/50; H01L 21/607

(52) U.S. Cl. 257/686; 438/109; 438/117; 257/E23.141; 257/788; 257/E21.499; 257/E21.518

(57) ABSTRACT

A semiconductor device includes a plurality of semiconductor packages each with a semiconductor element and a flexible board. The flexible board is wider than the semiconductor element and is electrically connected to the semiconductor element. The plurality of semiconductor packages are stacked on one surface of a mother board. The semiconductor element is positioned between the flexible boards of the semiconductor packages in adjacent layers. The flexible boards in the adjacent layers are joined together at junction portions positioned at a part of the flexible boards which sticks out from an area in which the semiconductor elements and the flexible boards overlap. A reinforcing resin is provided in at least a part of the area between the flexible boards in the adjacent layers and between the junction portion of the flexible boards and the corresponding semiconductor element. The reinforcing resin contacts at least a part of the adjacent flexible board.

This application is based upon and claims the benefit of priority from Japanese patent application No. 2008-216033, filed on Aug. 26, 2008, the disclosure of which is incorporated herein in its entirety by reference.

### BACKGROUND OF THE INVENTION

1. Field of the Invention

The present invention relates to a stack type semiconductor device with a reinforcing resin.

2. Description of the Related Art

For various types of information equipment such as large-sized computers, personal computers, and portable equipment, the performance has been improved and the sizes have been reduced year by year. Thus, the sizes of semiconductor elements mounted in these types equipment have been increased, whereas the areas of mounting boards on which the semiconductor elements are mounted have been reduced.

There has thus been a strong demand for high-density mounting techniques allowing many semiconductor elements to be mounted in a limited board area. To meet demand, techniques for stacking a plurality of semiconductor elements have been developed.

A stack type semiconductor device with a plurality of semiconductor elements is manufactured by using one semiconductor element and a wiring member to construct a semiconductor package and then by stacking a plurality of such semiconductor packages. Japanese Patent Laid-Open Nos. 2001-110978 and 2006-278863 disclose techniques of manufacturing a stack type semiconductor package by constructing semiconductor packages each with a semiconductor element and a bendably deformable flexible board, bending and joining the flexible boards of the respective semiconductor packages to a mother board. Furthermore, U.S. Pat. No. 7,186,920 discloses a technique of, in joining a plurality of flexible boards together, accurately stacking the flexible boards while preventing possible misalignment.

Japanese Patent Laid-Open No. 2001-110978 discloses a mounting structure of a semiconductor device in which a projecting electrode of a semiconductor chip is electrically connected to a mounting circuit board. Specifically, the semiconductor device is constructed by stacking a plurality of the mounting units. The mounting unit is composed of a semiconductor chip and a flexible intermediate connection layer. The intermediate connection layer has a conductive pattern to which the projecting electrode of the semiconductor chip is connected. The intermediate connection layer extends laterally at least from the connection position of the projecting electrode. An external terminal is provided at the end of the laterally extending intermediate connection layer. The external terminal of the intermediate connection layer is connected to the mounting circuit board.

Japanese Patent Laid-Open No. 2006-278863 discloses a semiconductor device including a stack type semiconductor package constructed by stacking a plurality of semiconductor packages each with a semiconductor element fixed to a flexible board and a wiring member made up of wiring. The semiconductor device further includes a base board on which an interface chip functioning as the interface between the stack type semiconductor package and external equipment is mounted. The wiring of the wiring member fixed to the semiconductor element extends from only one side of the semiconductor element and is connected to the base board.

U.S. Pat. No. 7,186,920 discloses a flexible wiring board including a first resin film, a first wiring film with a bottom surface fitted into the first resin film, and a second wiring film with a bottom surface tightly contacting the surface of the first resin film.

Japanese Patent Laid-Open No. 05-198737 discloses a stack type multichip semiconductor device. The stack type multichip semiconductor device includes a plurality of tape carrier packages in each of which a semiconductor chip is electrically connected to a film carrier tape with a wiring pattern formed on at least one surface thereof. The tape carrier packages are stacked via connector frames. An insulating film thicker than the wiring pattern is formed on at least one surface of the film carrier tape.

In the stack type semiconductor devices as described above, when the flexible board of one of the semiconductor packages is bent and joined to the mother board or the flexible board in the adjacent layer, a load is imposed on the junction portion. Thus, improving the reliability of the connection of the junction portion is desirable.

### SUMMARY

The present invention seeks to solve one or more of the above problems, or to improve upon those problems at least in part.

In one embodiment, a semiconductor device includes a plurality of semiconductor packages each with a semiconductor element and a flexible board. The flexible board is wider than the semiconductor element and is electrically connected to the semiconductor element. The plurality of semiconductor packages are stacked on one surface of a mother board. The semiconductor element is positioned between the flexible boards of the semiconductor packages in adjacent layers. The flexible boards in the adjacent layers are joined together at junction portions positioned at a part of the flexible boards which stick out from an area in which the semiconductor elements and the flexible boards overlap. A reinforcing resin is provided in at least a part of the area between the flexible boards in the adjacent layers and between the junction portion of the flexible boards and the corresponding semiconductor element. The reinforcing resin tightly contacts at least a part of the adjacent flexible board.

A method for manufacturing a semiconductor device in one embodiment includes preparing a plurality of semiconductor packages, stacking the plurality of semiconductor packages, bendably deforming flexible boards, and joining the flexible boards together. In preparing the plurality of the semiconductor packages, a plurality of semiconductor packages are prepared each of which includes a semiconductor element and a flexible board that is wider than the semiconductor element and that is electrically connected to the semiconductor element. In stacking the semiconductor packages, the plurality of semiconductor packages are sequentially stacked on one surface of the mother board in order of increasing width of the flexible board which is included in each semiconductor package. In bendably deforming the flexible boards, a junction tool is pressed against the flexible board of the semiconductor package located furthest from the mother board, to bendably deform a portion of the flexible board which sticks out from an area in which the semiconductor elements and the flexible boards overlap. In joining the flexible boards together, the junction tool is ultrasonically vibrated to join the portions of the flexible boards each of which sticks out from the area in which the semiconductor elements and the mother board together.

The present invention provides a semiconductor device offering high connection reliability and inhibiting possible improper electric continuity and electric short circuiting.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a schematic sectional view of a semiconductor device according to a second exemplary embodiment;

FIG. 1B is a schematic top view of a semiconductor device according to the second exemplary embodiment;

FIGS. 2A to 2F are step diagrams illustrating a process of manufacturing a semiconductor device according to the second exemplary embodiment;

FIGS. 3A to 3D are schematic diagrams showing the results of calculation of a process, in the manufacture of the semiconductor device, in which flexible boards are pressed against a junction tool and deformed, the calculation being based on a finite element method;

FIG. 4A is a schematic top view showing one of the flexible boards of individual semiconductor packages before junction;

FIG. 4B is a partial sectional view of the flexible board of the semiconductor package taken along line A-A′ in FIG. 4A;

FIG. 4C is a partial sectional view of the flexible board of the semiconductor package taken along line B-B′ in FIG. 4A;

FIG. 5A is a partial sectional view of the flexible boards after junction, the sectional view being taken along line A-A′ in FIG. 4A;

FIG. 5B is a partial sectional view of the flexible boards after junction, the sectional view being taken along line B-B′ in FIG. 4A;

FIG. 6A is a schematic sectional view of a semiconductor device according to a third exemplary embodiment;

FIG. 6B is a schematic top view of the semiconductor device according to the third exemplary embodiment;

FIGS. 7A and 7B are schematic step diagrams showing a method for manufacturing a semiconductor device according to the third exemplary embodiment;

FIG. 8A is a schematic top view showing flexible boards of semiconductor packages according to a fourth exemplary embodiment before junction;

FIG. 8B is a partial sectional view of the flexible board of the semiconductor package taken along line A-A′ in FIG. 8A;

FIG. 8C is a partial sectional view of the flexible board of the semiconductor package taken along line B-B′ in FIG. 8A;

FIG. 9 is a partial sectional view of the flexible boards of the semiconductor packages according to the fourth exemplary embodiment after junction;

FIG. 10A is a schematic sectional view of a semiconductor device according to a fifth exemplary embodiment;

FIG. 10B is a schematic top view of the semiconductor device according to the fifth exemplary embodiment;

FIG. 11A is a schematic sectional view of a semiconductor device according to a sixth exemplary embodiment; and

FIG. 11B is a schematic top view of the semiconductor device according to the sixth exemplary embodiment.

### DETAILED DESCRIPTION OF THE PREFERRED EMBODIMENTS

Before describing of the present invention, the sequence of ideas that were thought by the inventor to hit on this invention will be explained in order to facilitate the understanding of the present invention.

In a semiconductor device in which semiconductor packages, each including a semiconductor element and a bendably deformable flexible board, are stacked, the respective flexible boards are bent and joined to a mother board. To increase the mounting density of the stack type semiconductor packages, junction portions joining the flexible boards in the respective layers are preferably located at the same position as that of a junction portion joining the flexible boards and the mother board together. This is because the required area of the mother board is effectively reduced. In this case, to be joined to the same portion of the mother board, the plurality of flexible boards need to be stacked.

By change of the temperature of the device or by change of the condition of surroundings air during the use of the semiconductor device, a load is imposed on the junction portions joining the flexible boards and on the junction portion joining the mother board and the flexible boards together. A repelling force exerted by the bent flexible boards act on the junction portions. To prevent the junction portions from being destroyed by these loads, the peripheries of the junction portions is effectively reinforced with, for example, resin.

However, the gap between the flexible boards is small in the vicinity of each of the junction portions. Therefore, injecting resin into the gap after assembly of the semiconductor device is difficult. On the other hand, if the reinforcing resin is provided on the surface of each of the flexible boards before joining, the junction portion may be contaminated with the reinforcing resin, resulting in improper electric continuity at the junction portions. Thus, the reinforcing resin reinforcing the junction portions between the flexible boards and the junction portion between the flexible boards and the mother board together is desirably placed so as not to contaminate the junction portion.

If the bent flexible boards are stacked, the difference in bendable deformation between the flexible boards in the adjacent layers may misalign the flexible boards. The misalignment between the flexible boards may cause improper electric continuity or electric short circuiting between wires in the adjacent layers. Thus, the bent flexible boards need to be stacked without misalignment.

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

In a semiconductor device according to a first exemplary embodiment, the reinforcing resin is provided all over the area between portions of a plurality of the flexible boards which stick out from the area in which the semiconductor elements and the flexible boards overlap as well as all over the area between the junction portion of each of the flexible boards and the corresponding semiconductor element.

In a semiconductor device in an example of the first exemplary embodiment, the reinforcing resin is preferably a thermosetting resin.

In a semiconductor device in another example of the first exemplary embodiment, the reinforcing resin is preferably a thermoplastic resin.

In the semiconductor device according to the first exemplary embodiment, wires that are formed on the respective sides of a portion of the flexible board, which sticks out from the area in which the semiconductor elements and the flexible boards overlap, are paired. The paired wires are preferably electrically connected together.

In the semiconductor device according to the first exemplary embodiment, a plurality of the wires extended from at least one side of the semiconductor element are arranged linearly and parallel to each other.

In this case, a resin preventing possible misalignment in a direction perpendicular to a direction in which the wires extend is preferably provided on a part of each of the flexible board located on at least one side of the corresponding semiconductor element.

The thickness of the resin preventing the possible misalignment is preferably larger than the thickness of each of the wires and smaller than twice the thickness of the wire.

In an example of the first exemplary embodiment, the resin preventing the possible misalignment is preferably a thermoplastic resin.

In a method for manufacturing a semiconductor device according to an exemplary embodiment, a plurality of semiconductor packages each with a semiconductor element and a flexible board are stacked. The flexible board is wider than the semiconductor element, and is electrically connected to the semiconductor element. The flexible board includes wires on respective opposite surfaces thereof. The semiconductor packages are mounted on a mother board. The mother board and the flexible boards are electrically connected together via junction portions of the flexible boards. In this method, the plurality of semiconductor packages are sequentially stacked on the mother board in order of the increasing width of the flexible board which is included in each semiconductor package. Then, a junction tool is pressed against the semiconductor package located furthest from the mother board to bendably deform the plurality of flexible boards. The junction tool is then ultrasonically vibrated to join the flexible boards together and to join the flexible boards and the mother board together.

In the method for manufacturing the semiconductor device according to the exemplary embodiment, the temperature of the junction tool is preferably increased to harden a reinforcing resin in the vicinity of each of the junction portions.

Included in a semiconductor device according to another example of this exemplary embodiment are a plurality of semiconductor packages stacked on a mother board and each including a semiconductor element and a flexible board. The flexible board is larger than the semiconductor element in size, and is electrically connected to the semiconductor element. The flexible board has wires on respective opposite surfaces thereof. The respective flexible boards are bent and joined to the mother board directly or via another flexible board. Thus, the semiconductor elements are electrically connected together or to an external apparatus Before manufacturing, a reinforcing resin is provided on a part of each of the flexible boards, and the resin is provided between the wires of each of the flexible boards. This prevents the flexible boards from being misaligned during the manufacturing, while preventing the junction portions from being destroyed after junction.

In a method for manufacturing a semiconductor device according to yet another example of this exemplary embodiment, an unhardened reinforcing resin is provided on the top surface of each of flexible boards provided in respective semiconductor packages and at a position closer to a semiconductor element than to a junction target site to be joined to a flexible board making up another semiconductor package after junction. Thereafter, the flexible boards and a mother board are joined together. Wires are formed linearly and parallel to each other at a site of the flexible board of each of the semiconductor packages which project from the semiconductor element, that is, the portion of the flexible board which sticks out from the area in which the semiconductor elements and the flexible boards overlap. A resin such as a solder resist which has a thickness larger than the thickness of each of the wires and smaller than twice the thickness of the wire is provided on at least a part of the area between the wires.

With the plurality of semiconductor packages stacked on the mother board, when a junction tool is used to join the plurality of flexible boards and the mother board together, the flexible board in the upper layer is bendably deformed while sliding on the surface of the flexible board in the lower layer toward the semiconductor element. Thus, the reinforcing resin provided on the top surface of the flexible board in the lower layer is moved toward the semiconductor element by the flexible board in the upper layer.

In the above-described semiconductor device, before manufacturing, the reinforcing resin is provided only in an area which is closer to the semiconductor element than to a site (junction target site) of the flexible board which is to serve as a junction portion. This prevents a possible situation in which the flexible boards in the upper and lower layers slide on each other to contaminate the junction target site with the reinforcing resin. Furthermore, in the area which is closer to the semiconductor element than to the junction target site, the reinforcing resin contacts the flexible board. Thus, the reinforcing resin tightly contacts parts of the adjacent flexible boards without contaminating the junction target sites. As a result, the junction portions are prevented from functioning improperly because of the reinforcing resin. On the other hand, in the vicinity of each of the junction portions, possible deformation of the flexible boards in the upper and lower layers is restricted by the reinforcing resin. This prevents the junction portion from being destroyed.

Furthermore, preferably, the wires are arranged linearly and parallel to the respective opposite surfaces of each of the flexible boards in the upper and lower layers, and a resin such as a solder resist is provided between the wires on one of the surfaces of each of the flexible boards. Thus, when the flexible boards are joined together, the flexible board in the upper layer is permitted to slide on the surface of the flexible board in the lower layer in one direction. The resin provided between the wires further inhibits the flexible boards from sliding on each other in the other direction. As a result, during the junction, possible misalignment between the flexible boards is reduced.

The above-described configuration and method allow provision of a reliable semiconductor device that inhibits possible improper electric continuity and electric short circuiting.

### Second Exemplary Embodiment

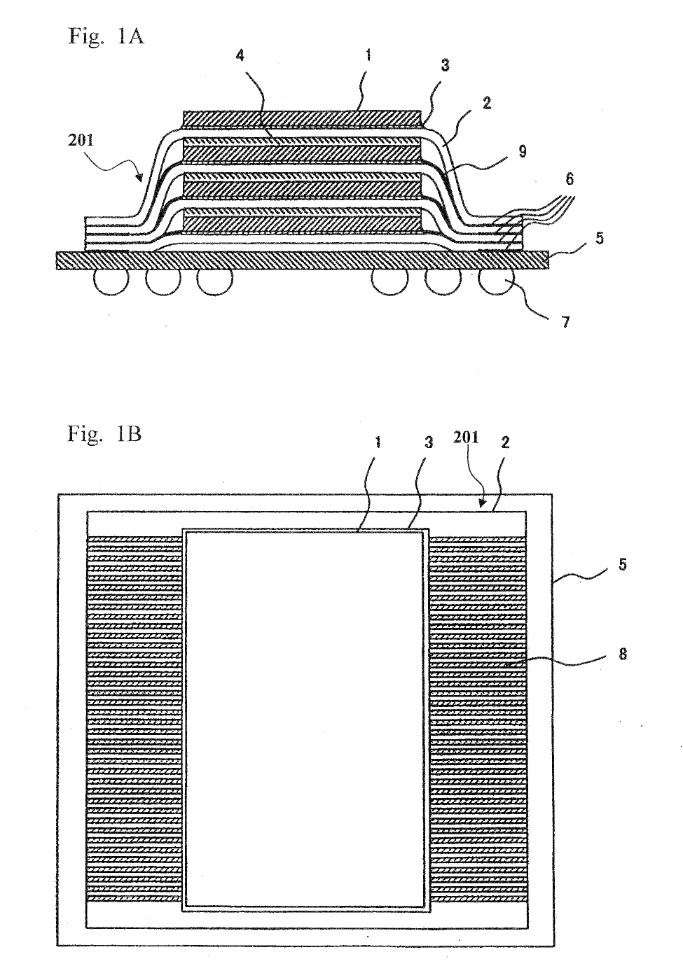

FIGS. 1A and 1B are a schematic sectional view and a schematic top view, respectively, of a semiconductor device according to a second exemplary embodiment. In these figures, the semiconductor device has four semiconductor packages stacked on the one surface (top surface) of mother board 5. Solder ball terminals 7 through which signals are transmitted to and received from external equipment are provided on another surface (bottom surface) of mother board 5.

Here, in the specification, for convenience, the direction of the mother board on which the semiconductor packages are mounted is defined as “top” side. The opposite direction is defined as a “bottom” side. However, in actuality, the mother board may be placed in any direction with respect to gravity.

The semiconductor package includes semiconductor elements 1, flexible boards 2, and sealing resins 3.

In this exemplary embodiment, mother board 5 is a glass epoxy board which is about 0.3 mm in thickness and which includes wires provided on the both surfaces. For example, the wires made up of copper. Each of semiconductor elements 1 is electrically connected to the corresponding one of flexible boards 2. Sealing resin 3 is formed between semiconductor element 1 and flexible board 2.

In this exemplary embodiment, the thickness of semiconductor element 1 is about 0.1 mm. Flexible board 2 has polyimide and wires provided on both surfaces of the polyimide. The polyimide has a thickness of about 0.04 mm. For example, the wires made up of copper. The copper wires on the both surfaces of the polyimide are electrically connected together by a via that penetrates the polyimide. For example, flexible board 2 is composed of a thin plate having a thickness of about 0.04 mm and can thus be easily bendably deformed. The surface of the copper wires is preferably plated with nickel, gold and so on. This prevents the wires from being oxidized or corroded, resulting in stable junction.

The sizes of semiconductor element 1, flexible board 2, and mother board 5 are not limited to the above-described examples but may vary. The materials of flexible board 2 and mother board 5 are not limited to the above-described examples. The wires formed on flexible substrate 2 and mother board 5 may be composed of any conductive material instead of copper.

Although not shown in the figures, semiconductor element 1 and flexible board 2 in the semiconductor package are electrically connected together via gold bumps. The connection part between semiconductor element 1 and flexible board 2 is sealed with sealing resin 3. In this exemplary embodiment, an epoxy resin is used as sealing resin 3. Instead of the epoxy resin, any of various reins may be used as sealing resin 3.

Each of semiconductor elements 1 is shaped like a plate. The plate surface of each of flexible boards 2 is larger than that of semiconductor element 1. That is, flexible board 2 is wider than semiconductor element 1. Thus, flexible board 2 sticks out from an area in which semiconductor elements 1 and flexible boards 2 overlap. Stick-out portion 201 of flexible board 2 is bent toward mother board 5. Respective flexible boards 2 are joined together at junction portions 6. The bottom surface of the flexible board 2 in the lowermost layer is joined to the top surface of mother board 5. In this case, junction portions 6 of the flexible boards in all the layers are provided at almost the same position in the plate surface of mother board 5. Junction portions 6 thus arranged at the same position enables a reduction in the size of mother board 5 compared to the junction portions arranged at different positions. This enables denser mounting. Here, flexible board 2 projecting from semiconductor element 1 refers to stick-out part 201 of flexible board 2 which sticks out from the area in which semiconductor elements 1 are stacked. That is, flexible board 2 projecting from semiconductor element 1 refers to part 201 of flexible board 2 which sticks out from the area in which semiconductor elements 1 and flexible boards 2 overlap.

In this exemplary embodiment, mother board 5 and flexible boards 2 are ultrasonically joined together, and flexible boards 2 are ultrasonically joined together. Furthermore, junction portions 6 provided on the both sides of the flexible board enable twice the amount of signals to be transmitted and received compared to the junction portion provided on one side of the flexible board.

In the semiconductor device according to this exemplary embodiment, reinforcing resin 9 is provided on the top surface of flexible boards 2 in the area between junction portions 6 of flexible boards 2 and semiconductor element 1. At least a part of the bottom surface of flexible board 2 located in the vicinity of junction portion 6 adheres to (tightly contacts) reinforcing resin 9. Thus, the restoring force (stress) of flexible board 2 prevents junction portions 6 joining adjacent flexible boards 2 from being separated from the corresponding flexible boards. Thus, the restoring force (stress) of flexible board 2 prevents junction portions 6 joining adjacent flexible boards 2 from being separated from the corresponding flexible boards. Further, the restoring force of flexible board 2 prevents junction portions 6 joining flexible boards 2 and mother board 5 together from being separated from the mother board 5. That is, reinforcing resins 9 reinforce junction portions 6.

Here, reinforcing resin 9 is provided in the area between flexible boards 2 in the adjacent layers and in at least a part of or all of the area between junction portions 6 of flexible boards 2 and semiconductor element 1. Reinforcing resin 9 according to the second exemplary embodiment may be a thermosetting resin. The thermosetting resin used as reinforcing resin 9 may be an epoxy resin, a phenol resin, a melamine resin, a urea resin, an unsaturated polyester rein, an alkyd resin, polyurethane, thermosetting polyimide and so on.

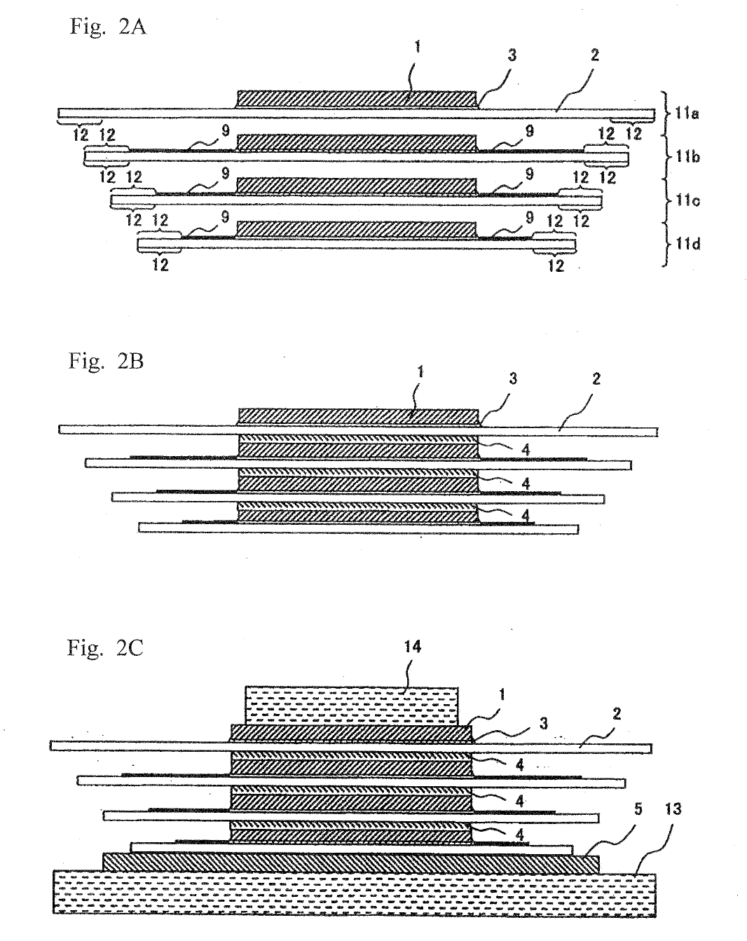

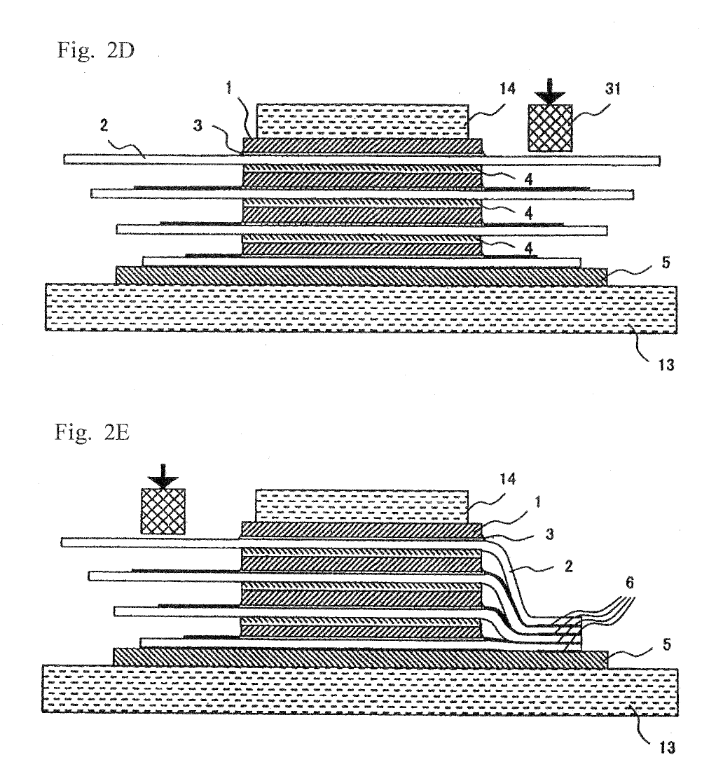

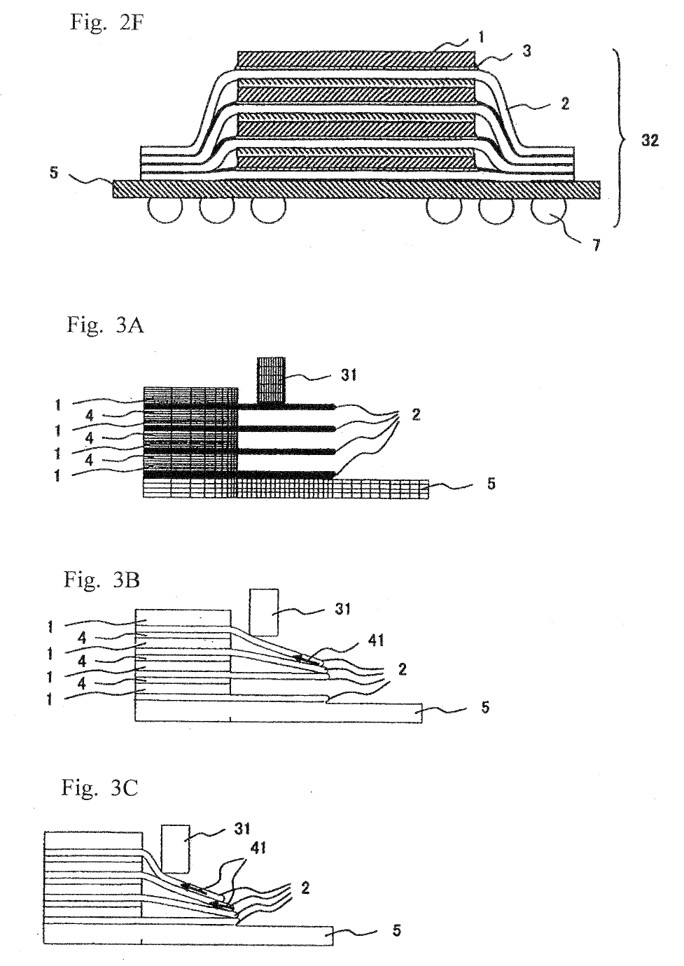

Now, with reference to FIGS. 2A to 2F, a method for manufacturing a semiconductor device of the second exemplary embodiment will be described.

First, as shown in FIG. 2A, a plurality of semiconductor packages 11a to 11d are prepared. The size of flexible board 2 of the semiconductor package to be located in a lower layer is set to be smaller than that of flexible board 2 in the semiconductor package stacked in the upper layer. That is, the flexible board in the lower layer is set to be narrower than the flexible board in the upper layer. Unhardened reinforcing resin 9 is provided on the top surface of flexible board 2 and in an area of flexible board 2 which is closer to semiconductor element 1 than to junction target site 12 positioned in the vicinity of the end of flexible board 2. Here, junction target site 12 is a portion of flexible board 2 to be joined to another flexible board later. Reinforcing resin 9 is unhardened but prevented from spreading to junction target site 12 owing to the viscosity of reinforcing resin 9. Unhardened reinforcing resin 9 need not be provided on semiconductor package 11a in the uppermost layer.

Then, as shown in FIG. 2B, semiconductor packages 11a to 11b are connected together via connectors 4. In the second exemplary embodiment, an elastomer is used as each of connectors 4. Connector 4 is not limited to the elastomer and may be any of various materials. Then, as shown in FIG. 2C, a plurality of semiconductor packages 11a to 11d are placed on mother board 5 fixed on stage 13. Fixing jig 14 is used to impose a load on semiconductor element 1 of semiconductor package 11a in the uppermost layer to fix semiconductor packages 11a to 11d. At this time, preferably, a through-hole (not shown in the drawings) is formed in the stage 13 such that mother board 5 can be sucked through the through-hole and fixed to the surface of stage 13.

Then, as shown in FIG. 2D, junction tool 31 is pressed against the top surface of flexible board 2 of semiconductor package 11a in the uppermost layer. Pressing of junction tool 31 bendably deforms flexible boards 2 other than the flexible board 2 in the lowermost layer. Consequently, the surfaces of flexible boards 2 are tightly contacted with each other, and the surfaces of flexible board 2 and mother board 5 are tightly contacted with each other. After the surfaces of flexible boards 2 are tightly contacted with one another, junction tool 31 is ultrasonically vibrated to metallically join the tightly contacted surfaces together. The temperature of junction tool 31 is thereafter increased to raise the temperature of the vicinity of junction portions 6. Reinforcing resins 9 are thus hardened. Here, unhardened reinforcing resins 9 positioned in the vicinity of the ends of flexible boards 2 located opposite reinforcing resins 9 hardened by junction tool 31 may be not hardened because unhardened reinforcing resins 9 are located far from junction tool 31.

After reinforcing resins 9 on one side are sufficiently hardened, junction tool 31 is moved away from junction portions 6. The junction on this side is thus completed.

Then, as shown in FIG. 2E, at junction portions 6 positioned in the vicinity of the opposite ends of flexible boards 2, flexible boards 2 and mother board 5 are joined together. As is the case with the above-described method, junction tool 31 is pressed against flexible boards 2 to ultrasonically join flexible boards 2 together. Junction tool 31 then generates heat to harden reinforcing resins 9.

Finally, as shown in FIG. 2F, fixing jig 14 is removed, and mother board 5 is removed from stage 13. Thereafter, solder ball terminals 7 are provided on the bottom surface of mother board 5 to complete stack type semiconductor device 32.

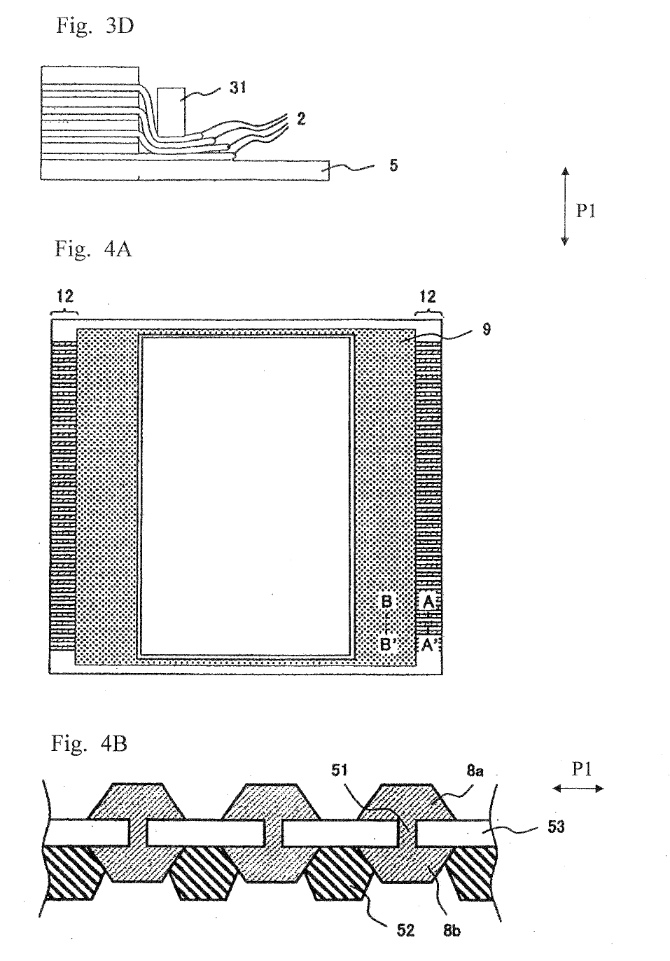

FIGS. 3A to 3D show the results of calculation of a process in which flexible boards 2 are pressed against junction tool 31 and deformed, the calculation using a finite element method. The calculation was performed under the condition that only one side of the semiconductor device is modeled and that flexible boards 2 in the respective layers have the same size (see FIG. 3A).

Junction tool 31 is pressed against flexible board 2 of semiconductor package 11 a to bendably deform flexible board 2 of semiconductor package 11a in the uppermost layer (the fourth layer from the bottom), which comes into contact with flexible board 2 in the third layer from the bottom. Junction tool 31 is further pressed to bendably deform flexible board 2 in the uppermost layer and flexible board 2 in the third layer from the bottom. Flexible board 2 in the third layer from the bottom comes into contact with flexible board 2 in the second layer from the bottom (see FIG. 3B). At this time, flexible board 2 in the uppermost layer is deformed while sliding on the surface of flexible board 2 in the third layer from the bottom, toward semiconductor element 1.

Junction tool 31 is further pressed to bendably deform flexible boards 2 in the uppermost layer and in the third and second layers from the bottom. Flexible board 2 in the second layer from the bottom comes into contact with the flexible board in the lowermost layer (the first layer from the bottom) (see FIG. 3C). At this time, flexible board 2 in the uppermost layer is deformed while sliding on the surface of flexible board 2 in the third layer from the bottom, toward semiconductor element 1. Flexible board 2 in the third layer from the bottom is deformed while sliding on the surface of flexible board 2 in the second layer from the bottom, toward semiconductor element 1.

Thus, flexible board 2 in the upper layer is bendably deformed to come into contact with flexible board 2 in the lower layer, and is deformed while sliding on the surface of flexible board 2 in the lower layer, toward semiconductor element 1.

As a result, since unhardened reinforcing resin 9 is provided at the position on flexible board 2 in the lower layer which is closer to semiconductor element 1 than junction target site 12, located in the vicinity of the end of flexible board 2 in the lower layer, flexible boards 2 can be joined together or flexible board 2 and mother board 5 can be joined together without contaminating junction target site 12 on the flexible board with reinforcing resin 9 (see FIG. 3D).

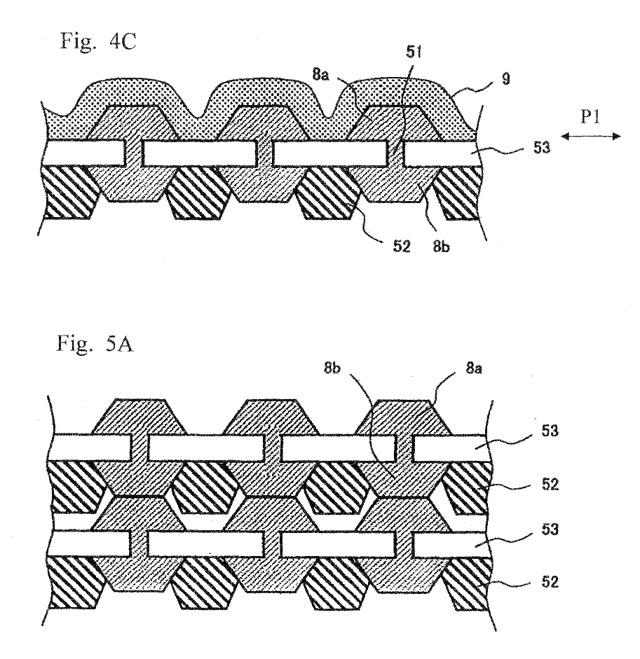

FIG. 4A is a schematic top view of semiconductor packages 11b to 11d in the layers other than the uppermost layer. FIGS. 4B and 4C are partial sectional views of flexible board 2 projecting from the semiconductor element. FIG. 4B is a sectional view of junction target site 12 in FIG. 4A taken along line A-A′. FIG. 40 is a sectional view of junction target site 12 in FIG. 4A taken along line B-B′ corresponding to a position closer to semiconductor element 1 than the position shown in FIG. 4B.

In each of the cross sections in FIGS. 4B and 4C, wire 8a on the top surface of flexible board 2 and wire 8b on the bottom surface of flexible board 2 are arranged so as to be paired. Wires 8a and 8b are electrically connected together through via 51 formed in polyimide tape 53.

In the second exemplary embodiment, via 51 is formed of the same material as that of wires 8a and 8b, that is, copper. Solder resists 52 are provided on the bottom surface of polyimide tape 53. No solder resist is provided on the top surface of polyimide tape 53. The thickness of each of solder resists 52 is larger than the thickness of wire 8b and smaller than twice the thickness of wire 8b. Referring to FIG. 4C, in the cross section taken along line B-B′ in FIG. 4A, unhardened reinforcing resin 9 is provided on the top surface of polyimide tape 53. In this case, wires 8a on the top surface of the flexible board are located under reinforcing resin 9. Thus, recesses and protrusions are formed on the surface of reinforcing resin 9.

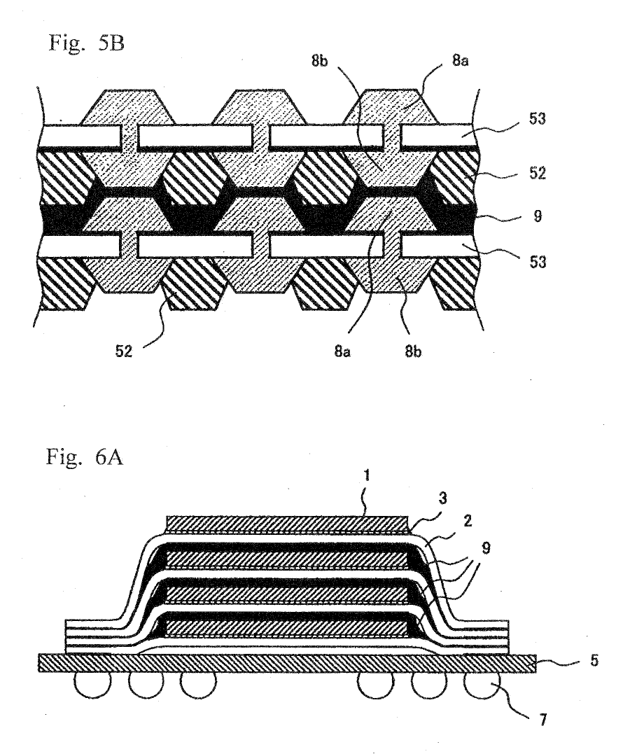

FIG. 5A is a partial sectional view taken along line A-A′ in FIG. 4A and shows that flexible board 2 in the upper layer is joined to flexible board in the lower layer. FIG. 5B is a partial sectional view taken along line B-B′ in FIG. 4A and shows that flexible board 2 in the upper layer is joined to flexible board in the lower layer.

As shown in FIGS. 4B and 4C, since the recesses and protrusions are formed on the surface of flexible board 2, when the flexible boards come into contact with each other, solder resists 52, each of which is thicker than wire 8b, guide sliding of the flexible board. Thus, the flexible boards can be prevented from being misaligned with respect to direction P1 perpendicular to the direction in which wires 8b extend. Furthermore, flexible boards 2 slide freely in the direction in which wires 8b extend. Thus, deformation of flexible boards 2 shown in FIGS. 3A to 3D is not prevented. Moreover, since the thickness of solder resist 52 is smaller than twice the thickness of wires 8a and 8b, solder resist 52 is prevented from coming into contact with polyimide 53 in the lower layer. In the junction portion 6 joining the flexible boards, space is created around each of the wires (see FIG. 5A).

On the other hand, referring to FIG. 5B, in the areas other than the junction portions 6, the gap between the flexible boards is filled with reinforcing resin 9. Thus, flexible boards 2 in the upper and lower layers are firmly fixed to each other. Solder resists 52 may be provided all over the area between wires 8b, that is, from the end of flexible board 2 to the end of semiconductor element 1 or limitedly provided within the range in which the effect of preventing possible misalignment can be exerted.

The above-described semiconductor element configuration and manufacturing method enable a reliable semiconductor device to be provided.

### Third Exemplary Embodiment

FIGS. 6A and 6B are a schematic sectional view and a schematic top view, respectively, of a semiconductor device according to a third exemplary embodiment.

The semiconductor device according to the third exemplary embodiment differs from that according to the second exemplary embodiment in that connectors 4, which are separate from reinforcing resins 9, are not used and semiconductor packages 11 are connected together via reinforcing resins 9.

That is, reinforcing resin 9 is also provided between the flexible board of the semiconductor package in the upper layer and the semiconductor element of the semiconductor package in the lower layer.

When semiconductor packages 11 are connected together via reinforcing resin 9, the need for separate connectors 4 is advantageously eliminated. On the other hand, before reinforcing resin 9 is hardened, semiconductor packages 11 have not been fixed to each other. Therefore, when the semiconductor packages are joined together, possible misalignment needs to be prevented.

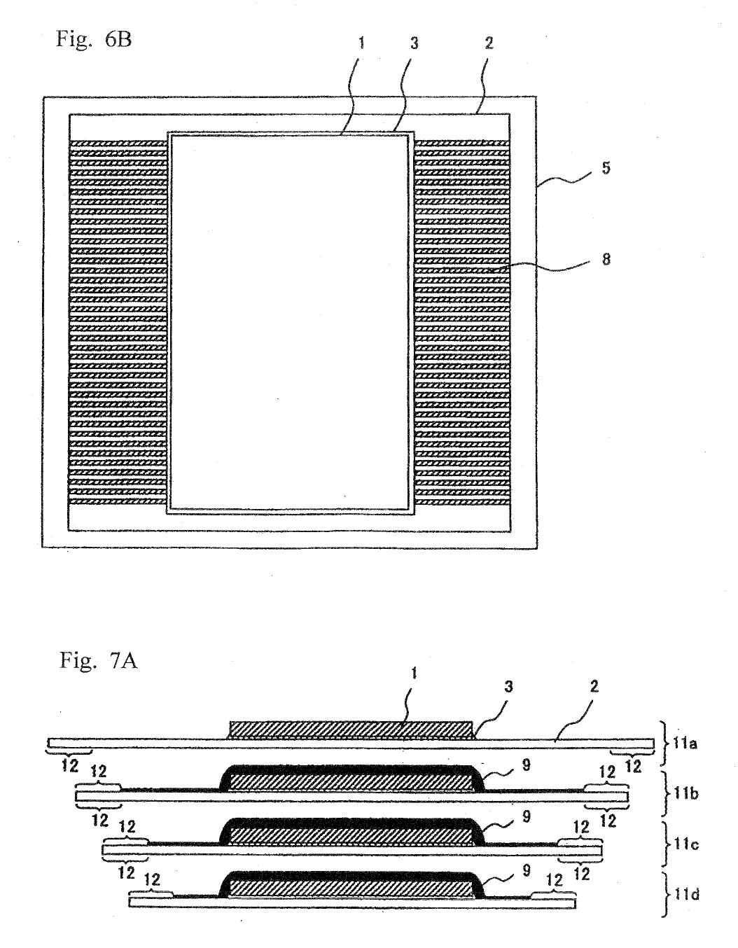

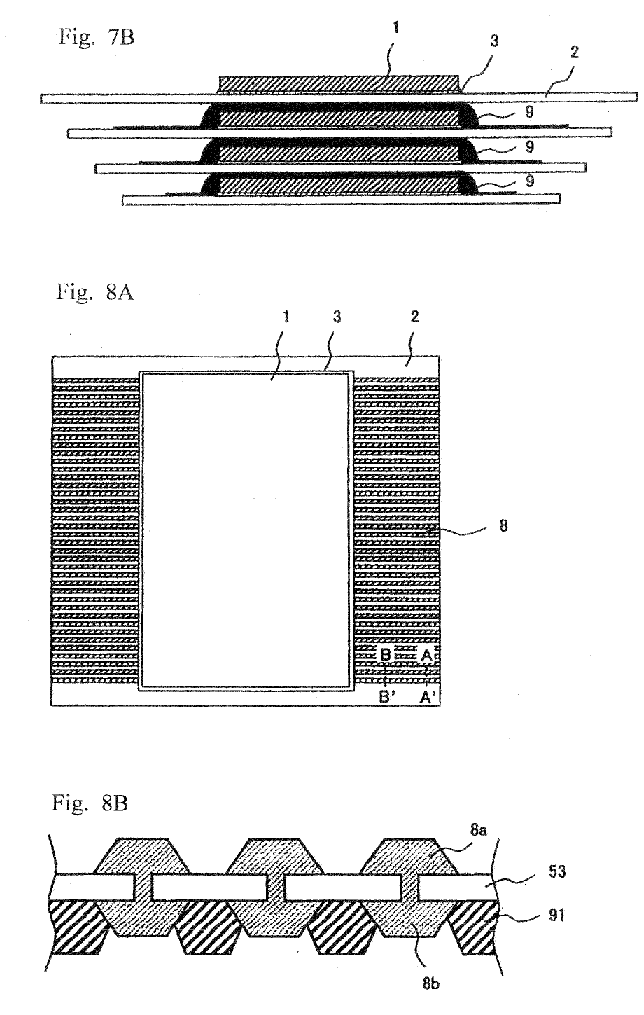

FIGS. 7A and 7B are schematic step diagrams of a method for manufacturing a semiconductor device according to the third exemplary embodiment. FIGS. 7A and 7B show schematic sectional views of the semiconductor device in respective steps.

First, as shown in FIG. 7A, a plurality of semiconductor packages 11a, 11b, 11c, and 11d are prepared. A difference between a manufacturing method according to the third exemplary embodiment and the manufacturing method according to the second exemplary embodiment is that unhardened reinforcing resin 9 is provided on the top surface of each of semiconductor elements 1 of semiconductor packages in all the layers other than the uppermost one.

Then, as shown in FIG. 7B, semiconductor packages 11a to 11d are connected together via reinforcing resins 9. At this time, reinforcing resins 9 are unhardened. Thus, attention needs to be paid to possible misalignment. To prevent possible misalignment, the end of the semiconductor element in the uppermost layer or a part of flexible board 2 located in the vicinity of the end is preferably held when the semiconductor package is fixed using fixing jig 14. This inhibits the possible misalignment of semiconductor element 1 along the mother board and the possible inclination of semiconductor element 1.

The subsequent steps are similar to those of the method described in the second exemplary embodiment with reference to FIG. 2C. However, when fixing jig 14 is used to fix the semiconductor package, an excessively heavy load may push out the unhardened reinforcing resin from the top surface of semiconductor element 1. Thus, preferably, the load imposed by fixing jig 14 is appropriately controlled. When the junction between the flexible boards is completed, reinforcing resins 9 located in the vicinity of junction portions 6 will be hardened. However, reinforcing resin 9 on the top surface of each of semiconductor elements 1 may have not been sufficiently hardened because heat from the junction tool failed to be sufficiently transmitted to reinforcing resin 9. Thus, after the junction is completed, the temperature of the stack type semiconductor device as a whole is preferably increased to harden reinforcing resins 9. The step of hardening reinforcing resins 9 may be carried out simultaneously with the step of attaching solder ball terminals 7 to the bottom surface of mother board 5.

### Fourth Exemplary Embodiment

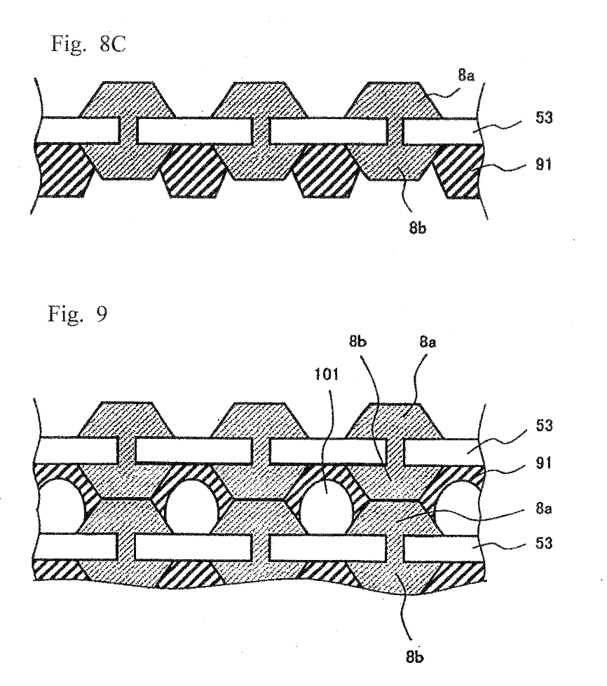

Now, a semiconductor device according to a fourth exemplary embodiment will be described. FIG. 8A is a schematic top view of a flexible board of a semiconductor package before junction. FIG. 8B is a partial sectional view of the flexible board of the semiconductor package taken along line A-A′ in FIG. 8A. FIG. 8C is a partial sectional view of the flexible board of the semiconductor package taken along line B-B′ in FIG. 8A. FIG. 9 is a partial sectional view showing flexible boards of semiconductor packages according to the fourth exemplary embodiment after junction.

In the second exemplary embodiment, solder resists 52 are provided on the bottom surface of the flexible board so that each of solder resists 52 is located between wires 8b. In contrast, in the fourth exemplary embodiment, thermoplastic resins 91 are provided on the bottom surface of the flexible board so that each of thermoplastic resins 91 is located between wires 8b. Moreover, the thermosetting resin used as reinforcing resin 9 in the second exemplary embodiment is not used in the semiconductor package according to the fourth exemplary embodiment.

Even when used in place of the solder resist, thermoplastic resin 91 offers a rigidity sufficient to prevent possible misalignment between the flexible boards at temperatures equal to or lower than the room temperature. Thus, as is the case with the second exemplary embodiment, flexible boards 2 can be joined together with high positional accuracy.

Thermoplastic resin 91 is preferably polypropylene, polyethylene, polystyrene, polyvinyl chloride, polyvinyl acetate, polytetrafluoroethylene (PTFE), an ABS resin (Acrylonitrile Butadiene Styrene copolymer), an AS resin (Acrylonitrile Stylene copolymer), or an acrylic resin.

According to a method for manufacturing a semiconductor device according to the fourth exemplary embodiment, when the temperature of junction tool 31 is increased after ultrasonic junction, a phenomenon different from that in the second exemplary embodiment may occur.

In the second exemplary embodiment, the temperature of the junction tool 31 is increased to harden the thermosetting resin located in the vicinity of junction portion 6 of the flexible board. However, in the fourth exemplary embodiment, the temperature of junction tool 31 is increased to soften and liquefy thermoplastic resin 91 located in the vicinity of junction portion 6. At this time, liquefied thermoplastic resin 91 is deformed by gravity, surface tension, or the like. Then, as shown in FIG. 9, thermoplastic resin 91 adheres not only to flexible board 2 in the upper layer but also to flexible board 2 in the lower layer.

Thereafter, heating of the flexible boards is stopped. The temperature of thermoplastic resin 91 then decreases to harden thermoplastic resin 91. As a result, thermoplastic resin 91 fixes the flexible boards in the upper and lower layers to each other. As described above, thermoplastic resin 91 enables junction portions 6 of the flexible boards to be reinforced without the need for the thermosetting resin used in the second exemplary embodiment. That is, thermoplastic resin 91 functions as a reinforcing resin provided on each of flexible boards 2.

### Fifth Exemplary Embodiment

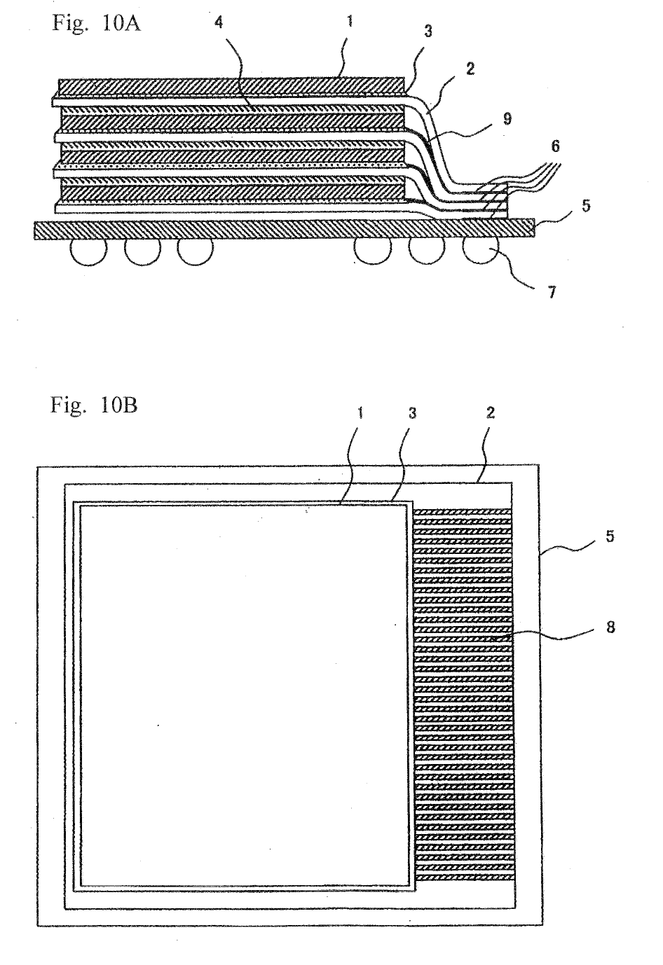

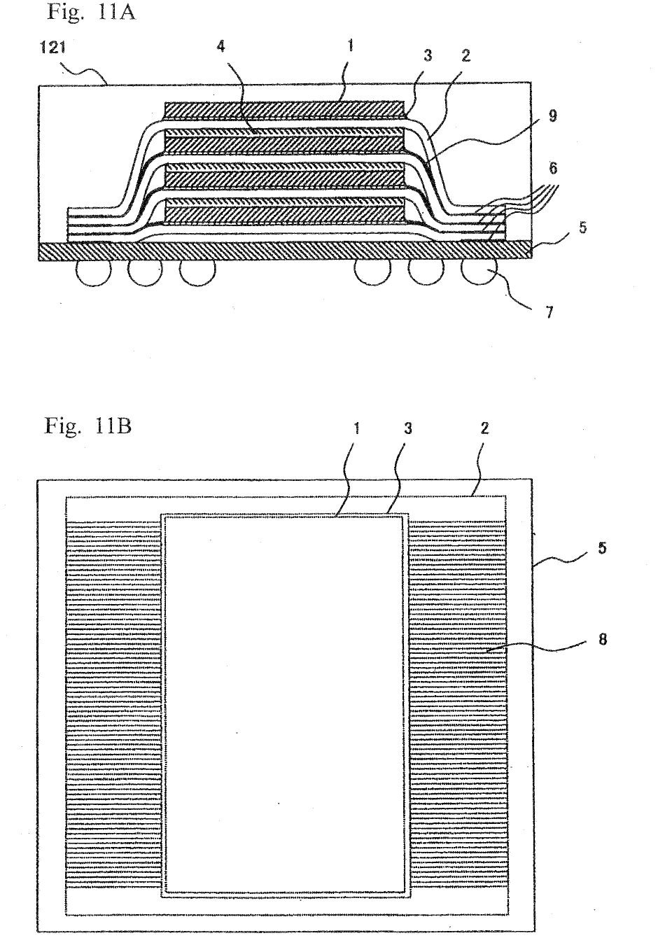

FIGS. 10A and 1-B are a schematic sectional view and a schematic top view, respectively, of a semiconductor device according to a fifth exemplary embodiment.

A difference between the semiconductor device according to the fifth exemplary embodiment and the semiconductor device according to the second exemplary embodiment is that junction portions 6 joining of the flexible boards or junction portions 6 joining of the flexible boards to the mother board are located only on one side of the mother board. Since junction portions 6 are located only on one side, the number of wires formed on the board is reduced to half. This reduces the amount of signals transmitted and received. However, on the other hand, a larger semiconductor element 1 can be mounted on mother board 5 of the same size. This enables an increase in capacity and density. Even though junction portions 6 are located only on one side of the mother board, the reinforcing resin described above in the first to fourth exemplary embodiments allows exertion of the effects of the present invention, including reinforcement of junction portions 6, acquisition of the reliability of the junctions, and prevention of possible misalignment between the flexible boards during manufacturing.

### Sixth Exemplary Embodiment

FIGS. 11A and 11B are a schematic sectional view and a schematic top view, respectively, of a semiconductor device according to a sixth exemplary embodiment.

A difference between the semiconductor device according to the sixth exemplary embodiment and the semiconductor device according to the second exemplary embodiment is that the area over mother board 5 as well as flexible boards 2 and semiconductor elements 1 are sealed with mold resin 121. Sealing with the mold resin 121 is performed after the junction between the flexible boards is completed.

Illustration of mold resin 121 is omitted in FIG. 11B in order to show the configuration of the semiconductor device. However, in actuality, the area over the mother board 5 is covered with mold resin 121.

Given that mold resin 121 can be sufficiently filled into a narrow gap, junction portions 6 need not be pre-reinforced by reinforcing resin 9 However, it is difficult to sufficiently fill mold resin 121 into the narrow gap between the flexible boards. Thus, without using reinforcing resin 9, space is likely to be formed in the narrow gap in the vicinity of junction portion 6 between the flexible boards. The space may reduce the reliability of the junction.

In contrast, in the sixth exemplary embodiment, reinforcing resin 9 is provided in the narrow gap in the vicinity of junction portion 6. This prevents a space in which no resin is filled from being formed in the vicinity of junction portion 6 after sealing with mold resin 121. Consequently, reliability of the junction portion 6 is prevented from being degraded. As described above, the present invention is effective for semiconductor devices sealed with mold resin 121.

While preferred embodiments of the present invention have been described using specific terms, such description is for illustrative purposes only, and it is to be understood that changes and variations may be made without departing from the spirit or scope of the following claims.

1. A semiconductor device comprising a plurality of semiconductor packages each with a semiconductor element and a flexible board which is wider than the semiconductor element and which is electrically connected to the semiconductor element,
wherein the plurality of semiconductor packages are stacked on one surface of a mother board,
the semiconductor element is positioned between the flexible boards of the semiconductor packages in adjacent layers,
the flexible boards in the adjacent layers are joined together at junction portions positioned at a part of the flexible boards which sticks out from an area in which the semiconductor elements and the flexible boards overlap,
a reinforcing resin is provided in at least a part of the area between the flexible boards in the adjacent layers and between the junction portion of the flexible boards and the corresponding semiconductor element, and
the reinforcing resin contacts at least a part of the adjacent flexible board.

2. The semiconductor device according to claim 1, wherein the reinforcing resin is provided all over the area between the flexible boards in the adjacent layers and between the junction portion of the flexible boards and the corresponding semiconductor element.

3. The semiconductor device according to claim 1, wherein the reinforcing resin is a thermosetting resin.

4. The semiconductor device according to claim 1, wherein the reinforcing resin is a thermoplastic resin.

5. The semiconductor device according to claim 1, wherein the flexible boards includes wires on respective opposite surfaces thereof,
the wires formed on the portion of the flexible board which sticks out from the area in which the semiconductor elements and the flexible boards overlap are paired on the respective opposite surfaces of the flexible board, and
the paired wires are electrically connected together,

6. The semiconductor device according to claim 5, wherein a plurality of the wires formed on the portion of the flexible board which sticks out from the area in which the semiconductor elements and the flexible boards overlap extend substantially linearly and parallel to each other.

7. The semiconductor device according to claim 6, wherein a resin preventing possible misalignment of each of the flexible boards in a direction perpendicular to a direction in which the wires extend is provided on one surface of the flexible board.

8. The semiconductor device according to claim 7, wherein the thickness of resin preventing possible misalignment of each of the flexible boards is larger than the thickness of each of the wires and smaller than twice the thickness of the wire.

9. The semiconductor device according to claim 7, wherein the resin preventing the possible misalignment of the flexible board also serves as the reinforcing resin and the resin is a thermoplastic resin.

10. A semiconductor device comprising:
a first semiconductor package including a first semiconductor element and a first flexible board on which the first semiconductor element is mounted; and
a second semiconductor package including a second semiconductor element and a second flexible board on which the second semiconductor element is mounted,
wherein the first semiconductor package is stacked on the second semiconductor package so as to position the second semiconductor element between the first flexible board and the second flexible board,
the first flexible board and the second flexible board are wider than the first semiconductor element and the second semiconductor element,
the first flexible board and the second flexible board are joined together at a junction portion positioned at a part of the flexible boards which sticks out from the second semiconductor element, and
a reinforcing resin contacting the first flexible board and the second flexible board is further provided in an area between the first flexible board and the second flexible board and between the second semiconductor element and the junction portion of the flexible boards.

11. A method for manufacturing a semiconductor device, the method comprising:
preparing a plurality of semiconductor packages each including a semiconductor element and a flexible board which is wider than the semiconductor element and which is electrically connected to the semiconductor element;
sequentially stacking the plurality of semiconductor packages on one surface of the mother board in order of the increasing width of the flexible board which is included in each semiconductor package;
pressing a junction tool against the flexible board of the semiconductor package located furthest from the mother board, to bendably deform a portion of the flexible board which sticks out from an area in which the semiconductor elements and the flexible boards overlap;
ultrasonically vibrating the junction tool to join the portions of the flexible boards each of which sticks out from the area in which the semiconductor elements and the flexible boards overlap and to join the portions that stick out and the mother board together.

12. The method for manufacturing the semiconductor device according to claim 11, wherein before manufacturing, a reinforcing resin is provided in at least a part of the area between the flexible boards in the adjacent layers and between each junction portion joining the flexible boards together and the corresponding semiconductor element.

13. The method for manufacturing the semiconductor device according to claim 12, wherein the reinforcing resin is a thermosetting resin, and
the method further comprises heating a vicinity of the junction portion to harden the reinforcing resin located in the vicinity of the junction portion.

14 The method for manufacturing the semiconductor device according to claim 12 wherein the reinforcing resin is a thermoplastic resin, and
the method further comprises heating a vicinity of the junction portion to soften the reinforcing resin located in the vicinity of the junction portion, and then cooling the vicinity of the junction portion to harden the reinforcing resin located in the vicinity of the junction portion.
